(19) United States
(12) Patent Application Publication
(10) Pub. No.: US 2026/0181849 A1
(43) Pub. Date: Jun. 25, 2026

(54) MEMORY ARCHITECTURES WITH BACKSIDE METAL ZERO (BM0) BIT-LINES

(71) Applicant: Intel Corporation, Santa Clara, CA (US)

(72) Inventors: John Reginald Riley, Sebastian, FL (US); Mauro J. Kobrinsky, Portland, OR (US); Seenivasan Subramaniam, Hillsboro, OR (US); Anandkumar Mahadevan Pillai, Fremont, CA (US); Fatih Hamzaoglu, Portland, OR (US); Zheng Guo, Hillsboro, OR (US)

(73) Assignee: Intel Corporation, Santa Clara, CA (US)

(21) Appl. No.: 18/999,748

(22) Filed: Dec. 23, 2024

(51) Int. Cl. H10B 10/10

(52) U.S. Cl. CPC H10B 10/10

(57) ABSTRACT

Memory architectures with backside metal zero (M0) bit-lines. SRAM bit-cells with the memory bit-lines traversing the memory bank in backside metal zero (BM0), rather than M0 or another metal layer in the metal stack. BM0 bit-lines have a larger width and pitch than M0, resulting in a reduced resistance and capacitance on the bit-lines.

### BACKGROUND

Some chiplets contain over 50% static random-access memory (SRAM) area. The scaling of monolithic static random-access memory (SRAM) has not kept pace with the scaling of other standard cell logic components, therefore, memory architectures that improve SRAM density are desirable.

### BRIEF DESCRIPTION OF THE DRAWINGS

FIG. 1 illustrates the backside of a SRAM cell with a backside metal zero (M0) bit-line, in accordance with various embodiments.

FIG. 2 illustrates two SRAM cells with backside M0 bit-lines tiled together, in accordance with various embodiments.

FIG. 3 is a simplified cross-sectional image of exemplary processing layers for reference of a die or wafer that may include the SRAM cell with a backside metal zero (M0) bit-line.

FIG. 4A is a simplified schematic illustration showing an SRAM memory component with two memory banks, in which both memory banks implement the backside M0 bit-lines.

FIG. 4B is a simplified schematic illustration showing an SRAM memory component implementing a hybrid solution, in which the memory bank nearest the sense amps implements fly-over M0, and the memory bank farther from the sense amp the backside M0 bit-lines.

FIG. 4C is a simplified schematic illustration showing an SRAM memory component implementing a hybrid solution, in which the memory bank nearest the sense amps implements fly-over M0, the memory bank after that implements bit-lines in metal two (M2), and the memory bank farthest from the sense amp the backside M0 bit-lines.

FIG. 5 illustrates an exemplary manufacturing flow for a backside of a SRAM cell with a backside metal zero (M0) bit-line, in accordance with embodiments described herein.

FIG. 6 is a schematic example of a SRAM for reference.

FIG. 7 is a top view of a wafer and dies that may be included in any of the embodiments disclosed herein.

FIG. 8 is a simplified cross-sectional side view showing the implementation of an integrated circuit on a die that may be included in any of the embodiments disclosed herein.

FIG. 9A-9D are simplified perspective views of example planar, FinFET, gate-all-around, and stacked gate-all-around transistors, as may be implemented in various embodiments.

FIG. 10 is a cross-sectional side view of a microelectronic assembly that may include any of the embodiments disclosed herein.

FIG. 11 is a block diagram of an example electrical device that may include any of the embodiments disclosed herein.

### DETAILED DESCRIPTION

As used herein, integrated circuit dies can include logic and/or memory and can be referred to as “chiplets.” Some chiplets, such as processor chiplets, can contain over 50% SRAM by area. Scaling reduces critical dimensions (CD) of features. The scaling of monolithic static random-access memory (SRAM), which is used in cache memory and other applications, has not kept pace with the scaling of other standard cell logic components, because of a number of technical challenges.

As the CDs of metal layers in a semiconductor stack are reduced, their resistance increases. Resistance of memory bit-lines (BL) is the major driver of SRAM memory cycle time. To remedy the increased resistance from scaling, the metal widths can be made wider, but that increases the BL capacitance, and BL capacitance is a major driver of SRAM read data latency. Additionally, the increased BL resistance and BL capacitance can increase power and slow the read data availability (increased read data latency). Moreover, as the widths of the BLs continue to increase, the individual bit-cells become wire-limited, and the bit-cell height hits a limit in its ability to be reduced.

Some available solutions use a “flying bit-line” using M2 for one or more bit-line(s). This solution has a significant power cost due to the increase in metal in individual SRAM cells (every SRAM bit-cell has metal 1 (M1) plus metal 2 (M2)). This approach also introduces a small amount of additional resistance associated with using vias to go up and down to the M2 in the stack. The M2 solution does not help with the metal scaling issue or fully reduce the increased capacitance issue mentioned above.

Embodiments disclosed herein propose a technical solution to the above-described technical problems in the form of memory architectures with backside metal zero (M0) bit-lines. Methods and apparatus move memory bit-lines from M0 to backside metal zero (BM0), taking advantage of the larger width and pitch of BM0, thereby reducing resistance and capacitance on the bit-lines. Embodiments enable faster TCC (cycle time) and faster TCQ (time from clock to queue or read latency). Further, creating hybrid architectures using some BM0 bit-lines and some bit-lines on other layers of metal can enable a savings in area. These concepts are developed in more detail below.

Embodiments can be recognized using SEM images focused the back side of an individual SRAM cell, where BM0 is used for memory bit-lines with vias that connect the backside BM0 upward (“punching up”) to the transistor. Likewise, the SRAM cell will not have M0 bit-lines with via connections punching down to the transistor.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

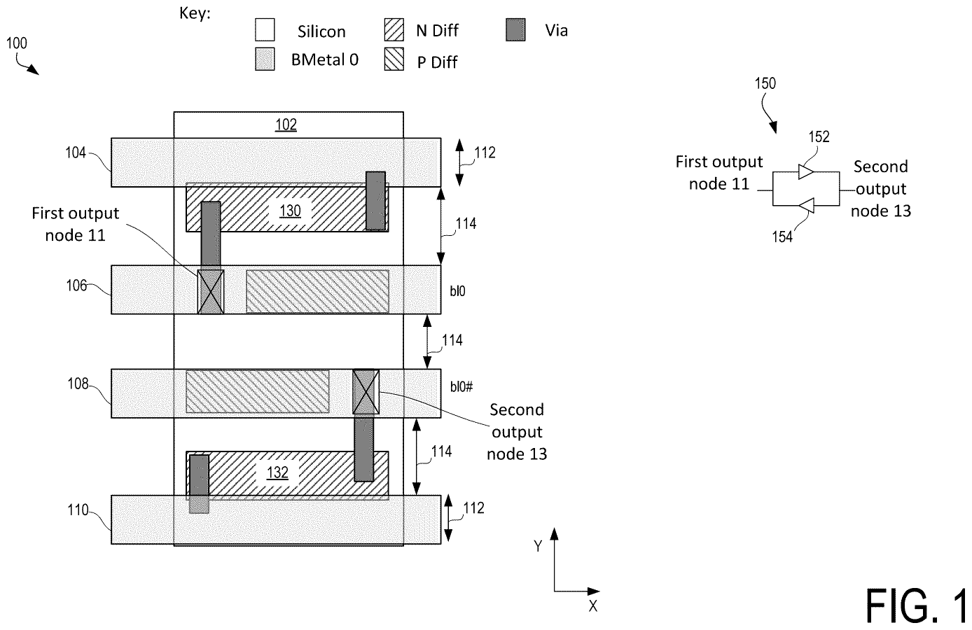

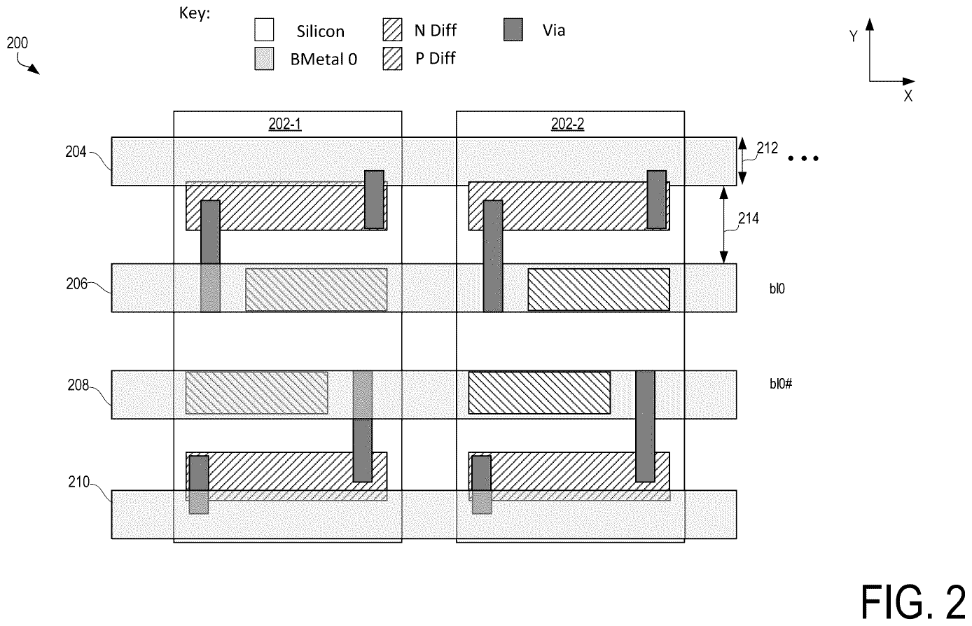

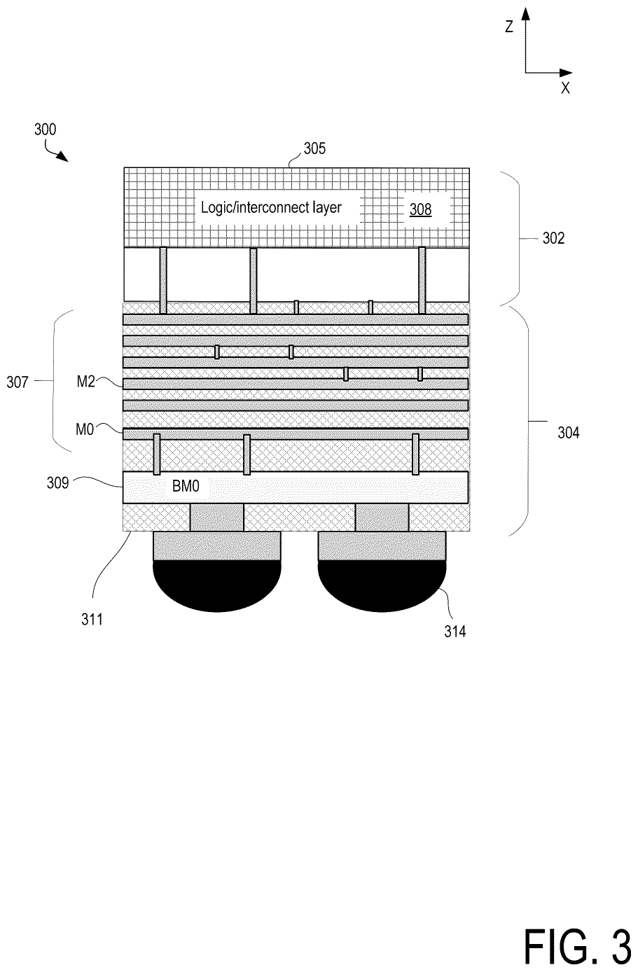

FIGS. 1-3 may be viewed together. FIG. 1 illustrates the backside of a SRAM cell with a backside metal zero (BM0) bit-line, and FIG. 2 illustrates the backside of two SRAM cells with BM0 bit-lines tiled together, in accordance with various embodiments, and FIG. 3 cross-sectional image 300 shows exemplary processing layers for reference of a substrate that may include the SRAM cell. As used herein, the “front side” of a wafer, die, or substrate is often referred to as an upper surface 305 that is used for processing. The “backside” 311 of the wafer, die, or substrate is the opposite surface from the front side, also referred to as a lower surface or bottom side.

In the backside view of embodiment 100 of the SRAM cell, silicon substrate 102 is depicted in white, and backside metal zero (BM0) is depicted in light grey. In various embodiments, the backside metal BM0 comprises copper. Embodiments of the semiconductor SRAM cell include four equal width and equally spaced (i.e., equal pitch) traces in BM0, the equally spaced (equal pitch) traces include a ground or VSS 104/204, depicted at the top of the SRAM cell, and a power supply or VCC 110/210, depicted at the bottom of the SRAM cell. In other embodiments, the VCC power supply may be omitted from the back side of the SRAM cell and may be on the front side instead.

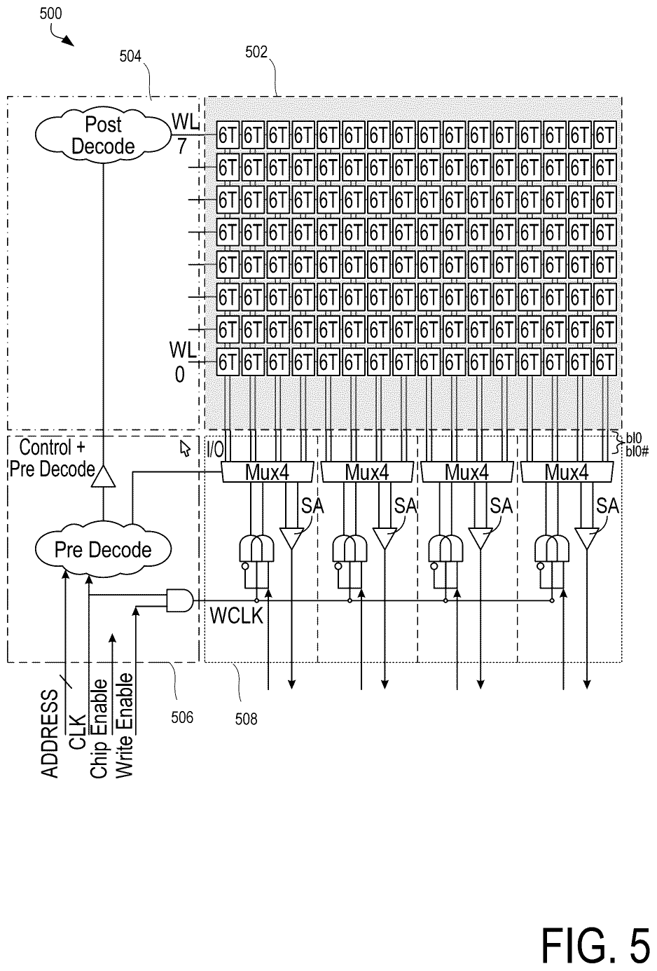

In between the power trace and ground trace are the bit-line and bit-line-bar lines. Some background first. As those with skill in the art will appreciate, embodiments of the SRAM cell are characterized by a storage portion 150 of the SRAM cell. The storage portion of the SRAM cell comprises a pair of cross-couple connected inverters, and further the inverters may each be implemented with a PMOS transistor and an NMOS transistor. Inverter 154 has the first output, node 11, which is also the (gate) input to inverter 152. The second output, node 13, is the output of inverter 152 and the (gate) input to the inverter 154. At the transistor level, node 11 is where a first source/drain of a P-type MOS transistor is electrically coupled to a first source/drain of a N-type MOS transistor and sharing the first gate input, and similarly, node 13 is where a second source/drain of a P-type MOS transistor is electrically coupled to a second source/drain of a N-type MOS transistor, sharing the second gate input. Node 11 and node 13 comprise conductive material and are also outputs from the SRAM cell. In application, the node 11 may be associated with the bit-line output of the SRAM cell and the node 13 may be associated with the bit-line-bar output of the SRAM, with each pair of bit lines disposed in correspondence to a column of the memory cells in the SRAM, e.g., as illustrated in FIG. 5.

Returning to the layout diagram of embodiment 100, the first output, node 11, is electrically coupled to bit-line-0 (bl0) 106 in BM0 and to a first N diffusion with a first via, and the second output, node 13, is electrically coupled to bit-line-0-bar (bl0 #) in BM0 and to a second N diffusion with a second via. Described differently, the SRAM memory cell comprises a first conductive via extending from a first region 130 of n-type diffusion to the lower surface (output node 11) and a second conductive via extending from a second region 132 of n-type diffusion to the lower surface (output node 13). The vias comprise a conductive material and provide an electrical path. The first node 11 and the second node 13 comprise a conductive material and can be observed and measured at the intersection of the respective via and the respective BM0 layer, as illustrated. In various embodiments, the first node and the second node comprise copper, and the first via and the second via also comprise copper.

The width 112/212 of the BM0 lines (104/204, 106/206, 108/208, and 110/210) are all the same, and the spacing 114/214 between neighboring BM0 lines is equal. In various embodiments, the BM0 may be implemented as 60 nanometer (60 nm) pitch wires +/−5 nm, with a 24 nm width (+/−2 nm) and a 36 nm (+/−2 nm) spacing. In various embodiments, the BM0 material may comprise copper. When two or more SRAM cells are tiled together, as illustrated in embodiment 200, SRAM cell 202-1 and SRAM cell 202-2, the BM0 traces continue across cells on the backside of the die or wafer, as shown.

For reference or context of the SRAM cell, the N diffusion has a right slanted diagonal, and the P diffusion has a left slanted diagonal. Dark grey is used to indicate the vias that connect the diffusion areas to respective traces of BM0.

The simplified wafer or substrate cross-sectional profile image 300 shows front end of line (FEOL 302) processing layers may be located toward the top, “front side,” or upper surface 305 and back end of line (BEOL 304) layers located toward the bottom or “backside” of the wafer in image 300. Any integrated circuits (ICs) that are assembled onto a wafer or die are generally attached at the upper surface 305, to the logic/interconnect layer 308. The bottom surface may have solder bumps 314, e.g. to attach to a solder silicon interposer or to an organic package.

In a generalized example associated with image 300, a first semiconductor wafer or die may include a substrate or semiconductor substrate, comprising layers of insulating material or dielectric material and/or oxides, interspersed with conductive interconnects (vias and traces, wherein the traces define various metal layers), and having conductive contacts on an upper surface 305 and lower surface or backside 311. The conductive interconnects and contacts generally comprise a metal, such as copper (Cu). In some embodiments, the conductive interconnects and contacts may include one or more of gold, tungsten, aluminum, titanium, tantalum, molybdenum, magnesium, and cobalt (W, Mo, Ti, Au, Mg, Ta, Co, Al) or tertiary systems or designer grain systems.

In most applications, the conductive interconnects are coupled to the integrated circuitry of a chiplet region or active region in a die, e.g., via a through silicon via (TSV) or through dielectric via (TDV). In various aspects of the disclosure, the conductive interconnects are to provide at least one electrical path from a node in the logic/interconnect layer and/or upper surface 305 through the substrate to a conductive contact on the backside 311.

As used herein, the metal stack is a region of the substrate or die in which multiple layers of metal are interleaved with insulating layers or dielectric layers. In some scenarios, the stack comprises six layers of metal (e.g., M0, M1, M2, M3, M4, and M5). In various embodiments, the upper metal layers 507 of the metal stack are thinner in the Z direction than the lower layers, e.g., the BM0 309 being a lower layer. As used herein, a thin layer of metal can be less than 20 nanometers +/−5% in the Z direction.

Various embodiments of the SRAM cell reference metal layers referred to as backside metal zero (BM0 309), metal zero (M0), and metal 2 (M2). As may be appreciated, there is a metal 1 (M1) layer between M0 and M2. As mentioned, in various embodiments, the BM0 may be implemented as 60 nanometer (60 nm) pitch wires, with a 24 nm width and a 36 nm spacing, which is wider and a larger spacing than that of M0 or M2, making it visually observable in TEM images.

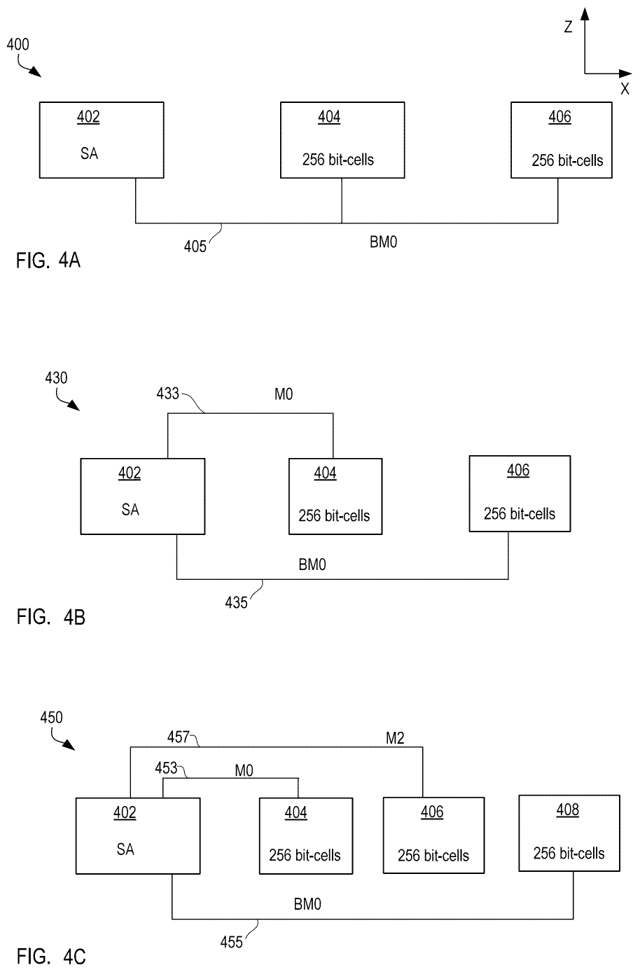

FIG. 4A, FIG. 4B, and FIG. 4C illustrate various non-limiting ways a monolithic SRAM component or SRAM module might implement embodiments of an SRAM cell with a backside M0 bit-line, and FIG. 5 is a simple schematic example embodiment 500 of a monolithic SRAM for reference. In various embodiments, the SRAM memory bank 502 comprises a monolithic, or two-dimensional, array of six transistor bit-cells (“6T cells”). The array size can vary in different applications, and the SRAM component can have more than one SRAM memory bank.

Eight word-lines are illustrated (WL7-WL0) and sixteen sets of bit-line/bit-line # (also referred to as bit-line and bit-line-bar) are illustrated (bl0/bl0 #-bl15/bl15 #). The associated SRAM memory bit-cells are indicated with “cell.” In SRAM memory bank 502, the individual bit-cells are electrically coupled to a respective word-line (WL, collectively, or WL0-WL7) input and electrically coupled to the conductive traces associated with the bit-line/bit-line # pairs (bl/bl #, collectively, or bl0/bl0 #-bl15/bl15 #). The bit-line/bit-line # pairs may also be referred to as a first node and a second node for a given SRAM cell, and the conductive traces associated with them may include copper.

The control and pre-decode circuitry 506 block drives the post-decode circuitry 504 block and the bit-line circuitry 508. The memory bank 502 is shaded gray. Collectively, the control and pre-decode circuitry 506 block, the post-decode circuitry 504 block, and the bit-line circuitry 508 block may be referred to as “peripheral logic” or “periphery circuitry.” Note that the sense amps (SA) are illustrated in the bit-line circuitry 508 portion of the periphery circuitry, at a lower edge of the memory bank 502 in the embodiment. In an application, the output arrows from the SA (sense amps) at the bottom of the array are collectively the SRAM output associated with a read command at a given address. In practice, there may be multiple blocks of memory, or memory banks, sharing one embodiment of periphery circuitry, as is illustrated with FIGS. 4A-4C.

In FIGS. 4A, 4B, and 4C, there is one instantiation of periphery circuitry, or more specifically, one sense amp (SA 402) system, and a first memory bank 404 and a second memory bank 406. FIG. 4C has an additional memory bank 408. In these examples, the memory bank size is 256 bit-cells. The first memory bank 404 is closest to the sense amps in the sense amp 402 system. FIG. 4A is an illustration of using the backside metal zero (BM0 405) layer to route the (first nodes) bit-line and (second nodes) bit-line # pairs across all of the bit-cells in both of the memory banks (memory bank 404 and memory bank 406).

FIG. 4B and FIG. 4C illustrate hybrid applications with embodiments. FIG. 4B embodiment 430 illustrates using the M0 layer 433 to route all of the (first nodes) bit-line and (second nodes) bit-line # pairs across the bit-cells in memory bank 404 (closest to the sense amp 402 system), and using the BM0 435 layer to route all of the (first nodes) bit-line and (second nodes) bit-line # pairs across the bit-cells in memory bank 406 (farther from the sense amp 402 system than memory bank 404). In various embodiments, the M0 layer 433 may comprise copper.

FIG. 4C embodiment 450 illustrates using the M0 layer 453 to route all of the (first nodes/second nodes) bit-line and bit-line # pairs across the bit-cells in memory bank 404 (closest to the sense amp 402 system), using a metal 2 (M2 457) layer to route all of the bit-line and bit-line # pairs across the bit-cells in memory bank 404 (middle distance from SA 402 system), and using the MB0 455 layer to route all of the bit-line and bit-line # pairs across the bit-cells in memory bank 408 (farther from the sense amp 402 system than memory bank 404 and memory bank 406). In various embodiments, the M0 layer 453 and the M2 layer 457 may comprise copper.

As mentioned, FIGS. 4A-4C are non-limiting. Other variations, such as routing the bit and bit-bar lines partially across an SRAM component in BM0, then feeding all or some of them to another metal layer, such as M2, and completing their traverse to the SA system on the M2 layer, can also be implemented.

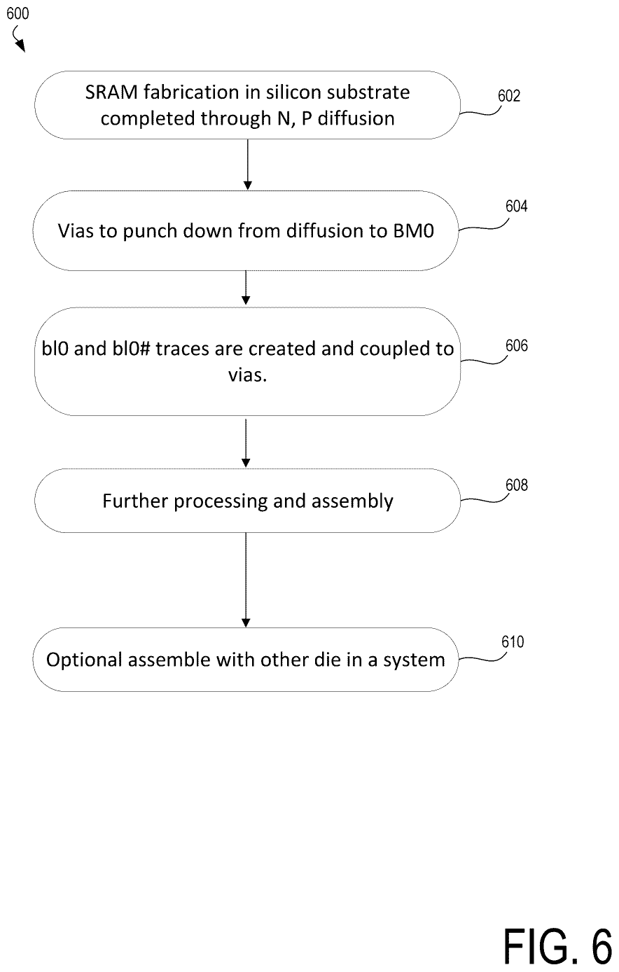

FIG. 6 illustrates an exemplary manufacturing flow for a SRAM cell with a backside metal zero (M0) bit-line, in accordance with embodiments described herein. At 602, a wafer or substrate in image 300 is manufactured with at least one SRAM bit-cell within the substrate. In other words, the N-diffusion area and P-diffusion area, and gate structure is built in addition to the source and drain for the 6T SRAM cell. The metal stack 307 may be fabricated to include up to the last needed metal layer (e.g., up to M5 or M6).

At 604, vias are fabricated to “punch down” to connect respective diffusion areas with backside metal zero (BM0).

At 606, the backside metal zero (BM0) lines, which are conductive traces comprising BM0 and meeting BM0 pitch, width and spacing specifications, are placed on the backside of the substrate or wafer. At 606, the vias from 604 are attached to respective bl0/bl0 # conductive traces.

At 608, further processing and assembly may be performed to thereby create a completed SRAM package component. For example, at 608, solder bumps may be attached at the lower surface or backside of the substrate/wafer, the wafer may be diced, and individual SRAM package components may be encapsulated.

At 610, the SRAM package component from 608 may be further assembled into a system or multi-die apparatus.

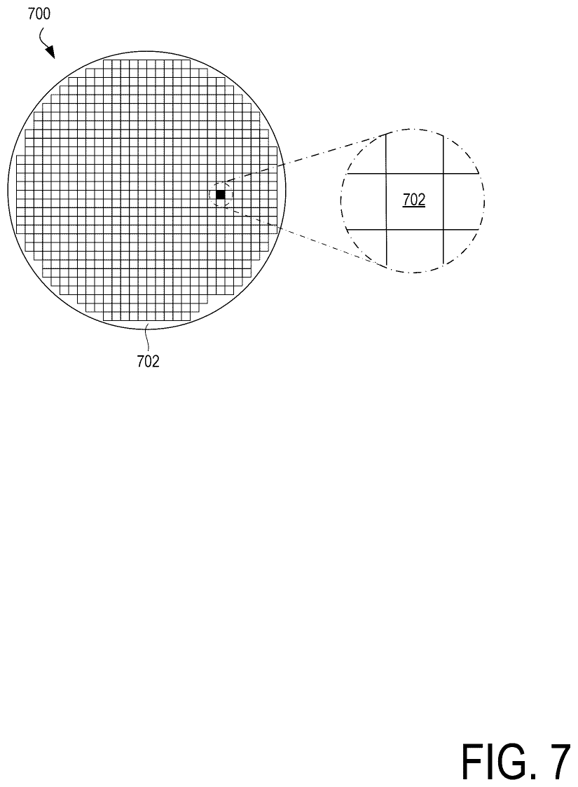

Thus, memory architectures with backside metal zero (BM0) have been introduced. Methods and apparatus employ wider BM0 for the bit and bit # (“bit-bar” or “bit-line-bar”) lines to advantageously make use of the lower resistance and lower capacitance from the BM0 layer, as compared to the thinner metal layers in the metal stack. Various embodiments also implement dedicated vias for electrical pathways from the respective bit and bit # outputs of SRAM bit-cells. The examples and embodiments described above may include, or be included in, embodiments described in connection with FIGS. 7-11.

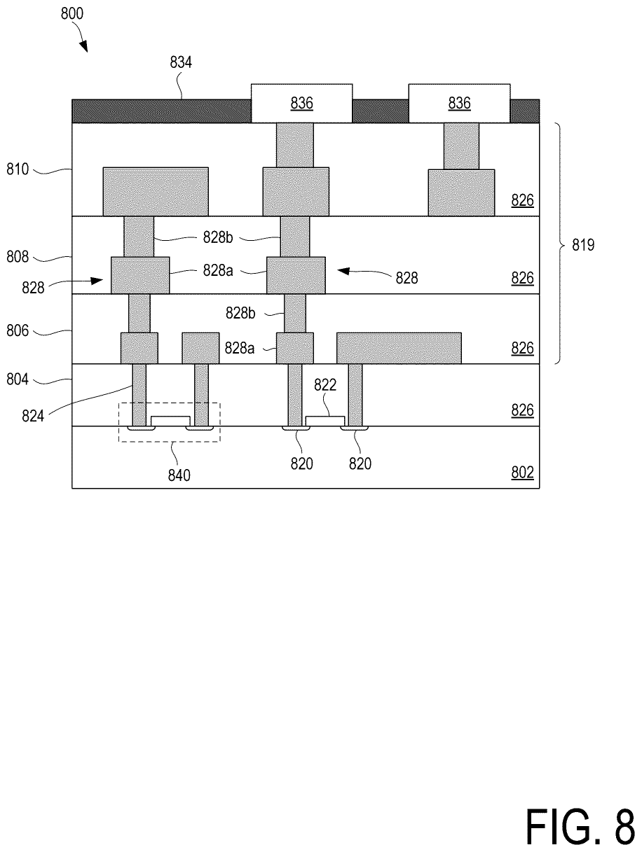

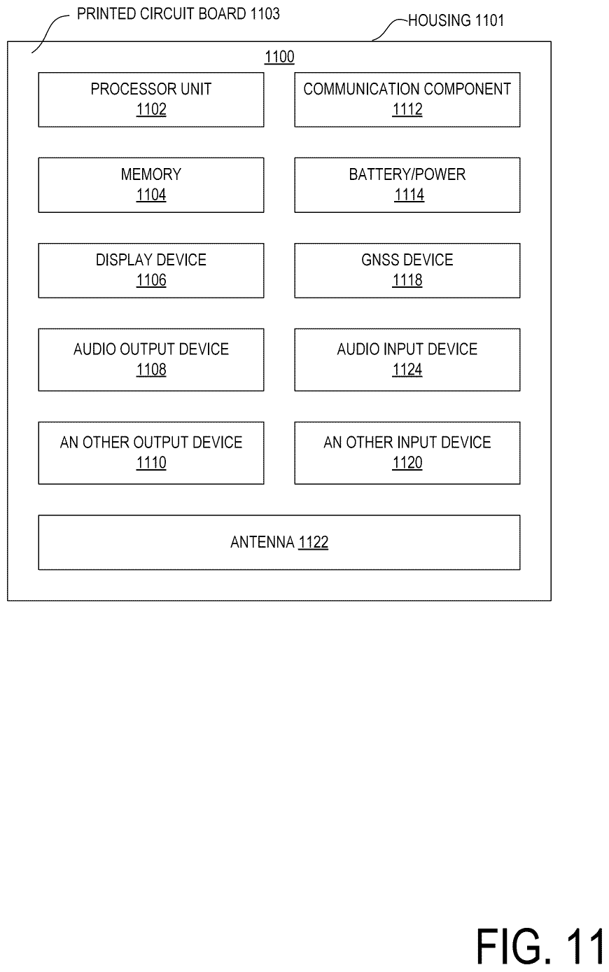

FIG. 7 is a top view of a wafer 700 and dies 702 that may be included in any of the embodiments disclosed herein. The wafer 700 may be composed of semiconductor material and may include one or more dies 702 formed on a surface of the wafer 700. After the fabrication of the integrated circuit components on the wafer 700 is complete, the wafer 700 may undergo a singulation process in which the dies 702 are separated from one another to provide discrete “chips” or destined for a packaged integrated circuit component. The individual dies 702, comprising an integrated circuit component, may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 702. For example, a memory array formed by multiple memory devices may be formed on a same die 702 as a processor unit (e.g., the processor unit 1102 of FIG. 11) or other logic that is configured to store information in the memory devices or execute instructions stored in the memory array. In some embodiments, a die 702 may be attached to a wafer 700 that includes other die, and the wafer 700 is subsequently singulated, this manufacturing procedure is referred to as a die-to-wafer assembly technique.

FIG. 8 is a cross-sectional side view of an integrated circuit 800 that may be included in any of the embodiments disclosed herein. One or more of the integrated circuits 800 may be included in one or more dies 702 (FIG. 7). The integrated circuit 800 may be formed on a die substrate 802 (e.g., the wafer 700 of FIG. 7) and may be included in a die (e.g., the die 702 of FIG. 7).

The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit 800 may be used. The die substrate 802 may be part of a singulated die (e.g., the dies 702 of FIG. 7) or a wafer (e.g., the wafer 700 of FIG. 7).

The integrated circuit 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820.

The gate 822 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may comprise a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be conducted to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuits having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828a/b of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit 800 with another component (e.g., a printed circuit board). The integrated circuit 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit 800 is a double-sided die, the integrated circuit 800 may include another metallization stack (not shown) on the opposite side of the device layer(s) 804. This metallization stack may include multiple interconnect layers as discussed above with reference to the interconnect layers 806-810, to provide electrically conductive paths (e.g., including conductive lines and vias) between the device layer(s) 804 and additional conductive contacts (not shown) on the opposite side of the integrated circuit 800 from the conductive contacts 836.

In other embodiments in which the integrated circuit 800 is a double-sided die, the integrated circuit 800 may include one or more through-silicon vias (TSVs) through the die substrate 802; these TSVs may make contact with the device layer(s) 804, and may provide electrically conductive paths between the device layer(s) 804 and additional conductive contacts (not shown) on the opposite side of the integrated circuit 800 from the conductive contacts 836. In some embodiments, TSVs extending through the substrate can be used for routing power and ground signals from conductive contacts on the opposite side of the integrated circuit 800 from the conductive contacts 836 to the transistors 840 and any other components integrated into the die of the integrated circuit 800, and the metallization stack 819 can be used to route I/O signals from the conductive contacts 836 to transistors 840 and any other components integrated into the die of the integrated circuit 800.

Multiple integrated circuits 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

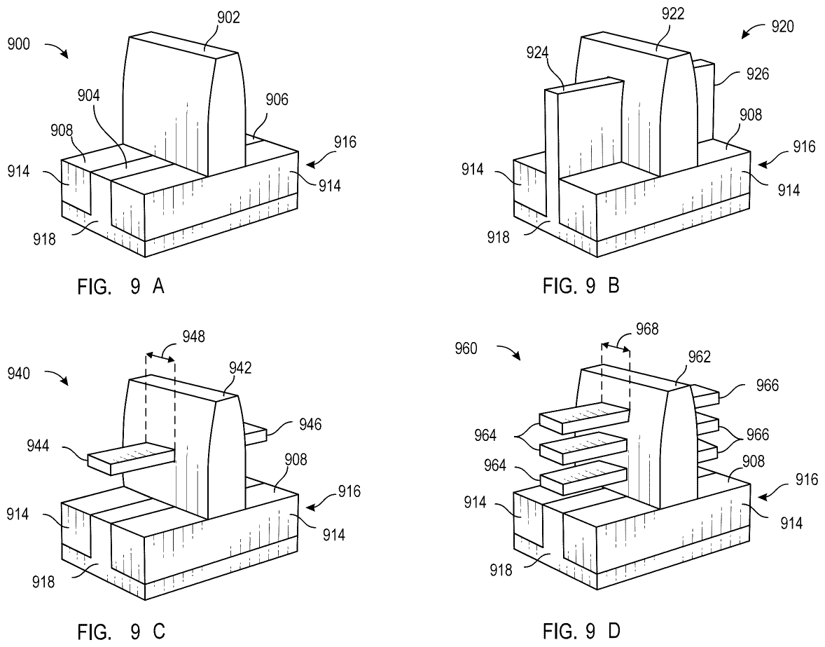

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 908. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 908.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extend from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

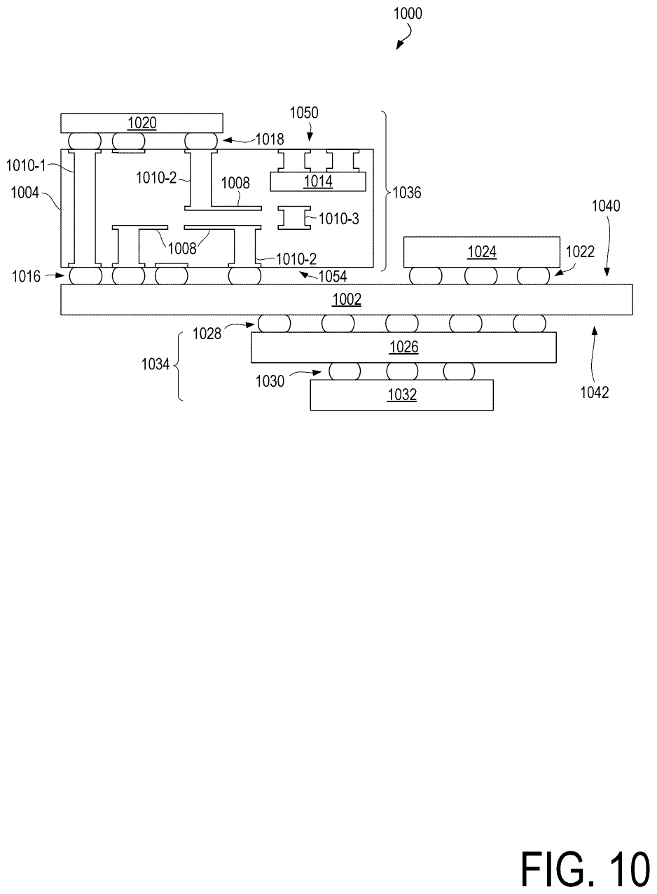

FIG. 10 is a cross-sectional side view of a microelectronic assembly 1000 that may include any of the embodiments disclosed herein. The microelectronic assembly 1000 includes multiple integrated circuit components disposed on a circuit board 1002 (which may be a motherboard, system board, mainboard, etc.). The microelectronic assembly 1000 may include components disposed on a first face 1040 of the circuit board 1002 and an opposing second face 1042 of the circuit board 1002; generally, components may be disposed on one or both faces 1040 and 1042.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The microelectronic assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit component that includes one or more integrated circuit dies (e.g., the die 702 of FIG. 7, the integrated circuit 800 of FIG. 8) and/or one or more other suitable components.

The unpackaged integrated circuit component 1020 comprises solder bumps attached to contacts on the die. The solder bumps allow the die to be directly attached to the interposer 1004. In embodiments where the integrated circuit component 1020 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and backside vias 1010-3 (that connect internal metal layers).

In some embodiments, the interposer 1004 can comprise a silicon interposer. Through-silicon vias (TSV) extending through the silicon interposer can connect connections on the first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The integrated circuit assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the embodiments disclosed herein. For example, any suitable ones of the components of the electrical device 1100 may include one or more of the disclosed embodiments, semiconductor assemblies, package assemblies, microelectronic assemblies 1000, integrated circuit components 1020, integrated circuits 800, integrated circuit dies 702, or structures disclosed herein. A number of components are illustrated in FIG. 11 as included in the electrical device 1100, but any one or more of these components may be omitted or duplicated, as suitable for the application. In some embodiments, some or all the components included in the electrical device 1100 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1100 can comprise one or more processor units 1102 that are heterogeneous or asymmetric to another processor unit 1102 in the electrical device 1100. There can be a variety of differences between the processor units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include power supply such as a battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an Ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Similarly, the word “overlaid” is used herein to denote a spatial relationship, being the past tense of overlay, to have been spread across, or superimposed on an object. Overlaid does not imply any particular procedure for placement. If a first layer is overlaid on a second layer, the first layer is also “located on” the second layer, as defined above.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a substrate comprising an upper surface and a lower surface; a static random access (SRAM) memory cell located between the upper surface and the lower surface; the SRAM memory cell comprising a first node and a second node; the lower surface comprising a first conductive trace and a second conductive trace, arranged at a pitch; the first conductive trace and the second conductive trace comprising a conductive material with a width equal to at least 20 nanometers; the first conductive trace electrically coupled to the first node with a first via; and the second conductive trace electrically coupled to the second conductive trace with a second via.

Example 2 includes the subject matter of Example 1, wherein: the substrate comprises dielectric material interleaved with at least a metal layer zero (M0), a metal layer 1 (M1), a metal layer 2 (M2) and a backside metal zero (BM0) layer; and the first conductive trace and the second conductive trace are in the backside metal zero (BM0) layer.

Example 3 includes the subject matter of Example 2, wherein the lower surface further comprises: a power supply trace comprising the conductive material and the width; and a ground trace comprising the conductive material and the width; wherein the first conductive trace and the second conductive trace are sandwiched between the power supply trace and the ground trace in the BM0 layer.

Example 4 includes the subject matter of any one of Examples 1-3, wherein the pitch is 60 nanometers +/−5 nanometers.

Example 5 includes the subject matter of any one of Examples 1-3, wherein the width is 24 nanometers +/−2 nanometers.

Example 6 includes the subject matter of any one of Examples 1-3, wherein the first conductive trace and the second conductive trace are separated by a space of 36 nanometers +/−5 nanometers.

Example 7 includes the subject matter of Example 6, further comprising solder balls attached to the lower surface.

Example 8 is a system comprising the subject matter of Example 7, and further comprising: a printed circuit board attached to the solder balls; and a processor architecture attached to the printed circuit board to communicate with the apparatus.

Example 9 is a package assembly, comprising: a die having an upper surface and a backside; a static random-access memory (SRAM) component positioned between the upper surface and the backside and comprising a plurality of SRAM memory cells; and the SRAM component further comprising periphery circuitry with a sense amp; wherein individual SRAM memory cells comprise: a first node; a first via to electrically couple the first node to the backside; a second node; and a second via to electrically couple the second node to the backside; a first conductive trace on the backside to electrically couple the first via to the sense amp; and a second conductive trace on the backside to electrically couple the second via to the sense amp; wherein the first conductive trace and the second conductive trace comprise a width of 24 nanometers +/−2 nanometers.

Example 10 includes the subject matter of Example 9, further comprising: a power supply trace on the backside, the power supply trace comprising the width; and a ground trace on the backside, the ground trace comprising the width; wherein the first conductive trace and the second conductive trace are sandwiched between the power supply trace and the ground trace.

Example 11 includes the subject matter of Example 9 or claim 10, wherein the die comprises: a silicon substrate comprising at least a metal layer zero (M0), a metal layer 1 (M1), a metal layer 2 (M2) and a backside metal zero (BM0) layer; M0, M1, and M2 are 20 nanometers +/−5% wide; and the first conductive trace and the second conductive trace are in the backside metal zero (BM0) layer.

Example 12 includes the subject matter of any one of Examples 9-11, wherein the first conductive trace and second conductive trace are arranged at a pitch of 60 nanometers +/−5 nanometers.

Example 13 includes the subject matter of Example 9, wherein the plurality of SRAM cells is arranged in a first bank, and wherein the SRAM component further comprises: a second bank comprising a second plurality of SRAM memory cells; wherein, in the second bank, individual SRAM memory cells of the second plurality of SRAM cells comprise: a third output; a third via to electrically couple the third output to a metal zero (M0) layer; a fourth output; a fourth via to electrically couple the fourth output to the M0 layer; a third conductive trace in the M0 layer to electrically couple the third via to the sense amp; a fourth conductive trace in the M0 layer to electrically couple the fourth via to the sense amp; and wherein the third conductive trace and fourth conductive trace are longer than either the first conductive trace or second conductive trace.

Example 14 includes the subject matter of Example 13, wherein the third conductive trace and fourth conductive trace are less than 20 nanometers wide +/−5 nanometers.

Example 15 includes the subject matter of any one of Examples 9-14, further comprising: solder balls attached to the backside; and a printed circuit board attached to the solder balls.

Example 16 includes the subject matter of Example 15, further comprising: a power supply attached to the printed circuit board and electrically coupled to the SRAM component.

Example 17 includes the subject matter of Example 15, wherein the first conductive trace and the second conductive trace comprise copper.

Example 18 is a method, comprising: fabricating a static random-access memory (SRAM) cell on a substrate having an upper surface and a backside; creating a first via to electrically couple a bit-line output to the backside; creating a second via to electrically couple a bit-line-bar output to the backside; electrically coupling the first via to a first conductive trace in a backside metal zero (BM0) layer in the substrate; electrically coupling the first via to a second conductive trace in the BM0 layer; and wherein the first conductive trace and second conductive trace are 24 nanometers wide +/−2 nanometers.

Example 19 includes the subject matter of Example 18, further comprising arranging the first conductive trace and the second conductive trace at a pitch of 60 nanometers +/−5 nm.

Example 20 includes the subject matter of Example 19, further comprising: fabricating a plurality of the SRAM cells; and implementing respective bit-line outputs and bit-line-bar outputs in the BM0 layer with respective widths of 24 nanometers wide +/−2 nanometers.

What is claimed is:

1. An apparatus, comprising:
a substrate comprising an upper surface and a lower surface;
a static random access (SRAM) memory cell located between the upper surface and the lower surface;
the SRAM memory cell comprising a first conductive via that extends from a first region of n-type diffusion to the lower surface and a second conductive via that extends from a second region of n-type diffusion to the lower surface;
the lower surface comprising a first conductive trace and a second conductive trace, arranged at a pitch;
the first conductive trace and the second conductive trace comprising a conductive material with a width equal to at least 20 nanometers;
the first conductive trace electrically coupled to the first conductive via; and
the second conductive trace electrically coupled to the second conductive via.

2. The apparatus of claim 1, wherein:
the substrate comprises dielectric material interleaved with at least a metal layer zero (M0), a metal layer 1 (M1), a metal layer 2 (M2) and a backside metal zero (BM0) layer; and
the first conductive trace and the second conductive trace are in the backside metal zero (BM0) layer.

3. The apparatus of claim 2, wherein the lower surface further comprises:
a power supply trace comprising the conductive material and the width; and
a ground trace comprising the conductive material and the width;
wherein the first conductive trace and the second conductive trace are sandwiched between the power supply trace and the ground trace in the BM0 layer.

4. The apparatus of claim 1, wherein the pitch is 60 nanometers +/−5 nanometers.

5. The apparatus of claim 1, wherein the width is 24 nanometers +/−2 nanometers.

6. The apparatus of claim 1, wherein the first conductive trace and the second conductive trace are separated by a space of 36 nanometers +/−5 nanometers.

7. The apparatus of claim 6, further comprising solder balls attached to the lower surface.

8. A system comprising the apparatus of claim 7, and further comprising:
a printed circuit board attached to the solder balls; and
a processor architecture attached to the printed circuit board to communicate with the apparatus.

9. A package assembly, comprising:
a die having an upper surface and a backside;
a static random-access memory (SRAM) component positioned between the upper surface and the backside and comprising a plurality of SRAM memory cells; and
the SRAM component further comprising periphery circuitry with a sense amp;
wherein individual SRAM memory cells comprise:
a first conductive via extending from a first region of n-type diffusion to the backside and a second conductive via extending from a second region of n-type diffusion to the backside;
a first conductive trace on the backside to electrically couple the first conductive via to the sense amp; and
a second conductive trace on the backside to electrically couple the second conductive via to the sense amp;
wherein the first conductive trace and the second conductive trace comprise a width of 24 nanometers +/−2 nanometers.

10. The package assembly of claim 9, further comprising:
a power supply trace on the backside, the power supply trace comprising the width; and
a ground trace on the backside, the ground trace comprising the width;
wherein the first conductive trace and the second conductive trace are sandwiched between the power supply trace and the ground trace.

11. The package assembly of claim 9, wherein the die comprises:
a silicon substrate comprising at least a metal layer zero (M0), a metal layer 1 (M1), a metal layer 2 (M2) and a backside metal zero (BM0) layer;
M0, M1, and M2 are 20 nanometers +/−5% wide; and
the first conductive trace and the second conductive trace are in the backside metal zero (BM0) layer.

12. The package assembly of claim 9, wherein the first conductive trace and second conductive trace are arranged at a pitch of 60 nanometers +/−5 nanometers.

13. The package assembly of claim 11, wherein the plurality of SRAM cells is arranged in a first bank, and wherein the SRAM component further comprises:
a second bank comprising a second plurality of SRAM memory cells;
wherein, in the second bank, individual SRAM memory cells of the second plurality of SRAM cells comprise:
a third conductive via extending from a third region of n-type diffusion to the backside and a fourth conductive via extending from a fourth region of n-type diffusion to the backside;
a third conductive trace in the M0 to electrically couple the third conductive via to the sense amp;
a fourth conductive trace in the M0 to electrically couple the fourth conductive via to the sense amp; and
wherein the third conductive trace and fourth conductive trace are longer than either the first conductive trace or second conductive trace.

14. The package assembly of claim 13, wherein the third conductive trace and fourth conductive trace are less than 20 nanometers wide +/−5 nanometers.

15. The package assembly of claim 9, further comprising:
solder balls attached to the backside; and
a printed circuit board attached to the solder balls.

16. The package assembly of claim 15, further comprising:
a power supply attached to the printed circuit board and electrically coupled to the SRAM component.

17. The package assembly of claim 15, wherein the first conductive trace and the second conductive trace comprise copper.

18. A method, comprising:
fabricating a static random-access memory (SRAM) cell on a substrate having an upper surface and a backside;
creating a first via to electrically couple a bit-line output to the backside;
creating a second via to electrically couple a bit-line-bar output to the backside;
electrically coupling the first via to a first conductive trace in a backside metal zero (BM0) layer in the substrate;
electrically coupling the first via to a second conductive trace in the BM0 layer; and
wherein the first conductive trace and second conductive trace are 24 nanometers wide +/−2 nanometers.

19. The method of claim 18, further comprising arranging the first conductive trace and the second conductive trace at a pitch of 60 nanometers +/−5 nm.

20. The method of claim 19, further comprising:
fabricating a plurality of the SRAM cells; and
implementing respective bit-line outputs and bit-line-bar outputs in the BM0 layer with respective widths of 24 nanometers wide +/−2 nanometers.
